(19) United States
(12) Patent Application Publication
(10) Pub. No.: US 2024/0244763 A1
(43) Pub. Date: Jul. 18, 2024

(54) Method for coating and forming novel material layer structure of high-frequency circuit board and article thereof

(71) Applicant: LongKai LI, Chongqing (CN)

(72) Inventor: LongKai LI, Chongqing (CN)

(21) Appl. No.: 18/617,496

(22) Filed: Mar. 26, 2024

Related U.S. Application Data
(63) Continuation of application No. 17/753,128, filed on Feb. 18, 2022.

(51) Int. Cl. H05K 3/44; H05K 1/02

(52) U.S. Cl. CPC H05K 3/44; H05K 1/0237; H05K 2203/11

(57) ABSTRACT

The present invention discloses a method for coating and forming a novel material layer structure of a high-frequency circuit board, comprising the steps of: (1) coating a synthetic liquid film on a copper foil; (2) delivering the same to a tunnel oven for roasting, and forming a cured film on the copper foil to obtain a single-sided board; (3) coating a layer of synthetic liquid high-frequency material on the cured film; and (4) delivering the same to the tunnel oven for roasting until the synthetic liquid high-frequency material layer becomes a semi-cured high-frequency material layer so as to obtain a novel material layer structure of a high-frequency circuit board. An article prepared by performing the above methods is also disclosed. The prepared novel material layer structure of the high-frequency circuit board has the performance of high-speed transmission of high-frequency signals, and can adapt to the current high-frequency and high-speed trend from wireless network to terminal applications, especially for new 5G technology products. It can be used as a circuit board preparation material to make a single-layer circuit board, a multi-layer flexible circuit board and a multi-layer soft-hard combined board, which brings great convenience to circuit board preparation and simplifies the process.

### CROSS REFERENCES TO RELATED APPLICATION

This application is a continuation of U.S. application Ser. No. 17/753,128, entitled “Method for coating and forming novel material layer structure of high-frequency circuit board and article thereof”, filed Feb. 18, 2022, and the entire contents of which are incorporated herein by reference.

### TECHNICAL FIELD

The present invention relates to the field of circuit boards, and more particularly, to a method for coating and forming a novel material layer structure of a high-frequency circuit board and an article thereof.

### BACKGROUND ART

At present, the communication frequency is overall high-frequency from the communication network to the terminal application. High-speed and large-capacity applications emerge endlessly. As wireless networks transition from 4G to 5G in recent years, network frequencies continue to rise. According to the 5G development roadmap shown in the relevant data, the future communication frequency will be promoted in two stages. The first phase aims to increase the communication frequency to 6 GHz by 2020, and the second phase to further increase it to 30-60 GHz by 2020. In the market application, the signal frequency of terminal antennas such as smart phones is increasing. There are more and more high-frequency applications, which acqure more and more demand for high-speed and large-capacity. To adapt to the current trend of high-frequency and high speed from wireless networks to terminal applications, soft boards, as antennas and transmission lines in terminal devices, will also be subject to technological upgrading.

The conventional soft board has a multi-layer structure composed of a copper foil, an insulating substrate, a cover layer and the like, with the copper foil as a conductor circuit material, a PI film as a circuit insulating substrate, and a PI film and an epoxy adhesive as a cover layer for protecting and isolating a circuit, which are processed into a PI soft board by a certain process. Since the properties of the insulating substrate determine the final physical and electrical properties of the soft board, the soft board needs to use substrates with various performance characteristics in order to adapt to different application scenarios and functions. Polyimide (PI) is the most widely used soft board substrate at present. However, due to the larger dielectric constant and loss factor, higher moisture absorption and poor reliability of PI substrate, the high-frequency transmission loss of PI soft board is serious and its structural characteristics are poor, which cannot adapt to the current high-frequency and high-speed trend. Therefore, with the emergence of new 5G technology products, the signal transmission frequency and speed of existing circuit boards have been difficult to meet the requirements of 5G technology products.

Meanwhile, in the preparation technique, there are many problems in the traditional multi-layer flexible circuit board or multilayer combination of hard and soft boards, such as more process flows, complex manufacturing process, and higher power consumption and signal transmission loss in circuit board performance.

### SUMMARY OF THE INVENTION

In view of the above-mentioned deficiencies, it is an object of the present invention to provide a method for coating and forming a novel material layer structure of a high-frequency circuit board and an article thereof. The prepared novel material layer structure of the high-frequency circuit board has the performance of high-speed transmission of high-frequency signals, and can adapt to the current high-frequency and high-speed trend from wireless network to terminal applications, especially for new 5G technology products. The novel material layer structure of the circuit board, as an integral structure, can be used as a manufacturing material of the circuit board in a subsequent manufacturing process of the circuit board to prepare a circuit board structure such as a single-layer circuit board, a multi-layer flexible circuit board and a multi-layer soft-hard combined board, which brings great convenience to the subsequent manufacturing of the circuit board, simplifies the manufacturing process, accelerates the manufacturing speed of the circuit board, and reduces production costs.

The technical solution adopted by the invention for achieving the above purpose is as follows.

A method for coating and forming a novel material layer structure of a high-frequency circuit board is characterized by comprising the steps of:
(1) placing a copper foil on a coater, and coating a synthetic liquid film on the copper foil with the copper foil as a substrate;
(2) delivering the copper foil coated with the synthetic liquid film into a tunnel oven, and successively passing the same through a plurality of sections of heating and roasting zones in the tunnel oven at a speed of 0.5-20 m/s for roasting in sections, so as to form a cured film on the copper foil, and obtaining a single-sided board;
(3) placing the single-sided board on a coater, and coating the cured film of the single-sided board with a layer of a synthetic liquid high-frequency material;
(4) delivering the single-sided board coated with the synthetic liquid high-frequency material layer to the tunnel oven, and successively passing the same through a plurality of sections of heating and roasting zones in the tunnel oven at a speed of 0.5-20 m/s for roasting in sections until the synthetic liquid high-frequency material layer on the single-sided board becomes a semi-cured high-frequency material layer, so as to obtain a novel material layer structure of a high-frequency circuit board.

As a further improvement of the invention, the step (4) further comprises the steps of applying a release paper or PET release film on the back of the semi-cured high-frequency material layer.

As a further improvement of the present invention, in the step (1), the synthetic liquid film is any one of a synthetic liquid PI film, a synthetic liquid MPI film, a synthetic liquid LCP film, a synthetic liquid TFP film, and a synthetic liquid PTFE film.

As a further improvement of the present invention, in the step (3), the synthetic liquid high-frequency material layer is a synthetic liquid MPI film, a synthetic liquid LCP film, a synthetic liquid TFP film, a synthetic liquid PTFE film, a synthetic liquid LDK high-frequency functional adhesive, or a synthetic liquid mixture of a liquid LDK high-frequency functional adhesive and a liquid copper ion migration resistant adhesive.

As a further improvement of the present invention, the synthetic liquid LDK high-frequency functional adhesive is obtained by adding Teflon or LCP material to a liquid AD adhesive; and the liquid copper ion migration resistant adhesive is obtained by adding a copper ion scavenger to the liquid AD adhesive, followed by high purification.

As a further improvement of the present invention, in the step (2), the plurality of sections of heating and roasting zones in the tunnel oven at least comprise a first heating and roasting zone, a second heating and roasting zone, a third heating and roasting zone, a fourth heating and roasting zone, a fifth heating and roasting zone and a sixth heating and roasting zone, wherein the temperature range of the first heating and roasting zone is 60° C.-100° C.; the temperature range of the second heating and roasting zone is 100° C.-200° C.; the temperature range of the third heating and roasting zone is 200° C.-300° C.; the temperature range of the fourth heating and roasting zone is 300° C.-400° C.; the temperature range of the fifth heating and roasting zone is 400° C.-500° C.; and the temperature range of the sixth heating and roasting zone is 60° C.-100° C.

As a further improvement of the present invention, in the step (4), the plurality of sections of heating and roasting zones in the tunnel oven at least comprise a first heating and roasting zone, a second heating and roasting zone, a third heating and roasting zone, a fourth heating and roasting zone, a fifth heating and roasting zone and a sixth heating and roasting zone, wherein the temperature range of the first heating and roasting zone is 60° C.-100° C.; the temperature range of the second heating and roasting zone is 100° C.-200° C.; the temperature range of the third heating and roasting zone is 200° C.-300° C.; the temperature range of the fourth heating and roasting zone is 300° C.-400° C.; the temperature range of the fifth heating and roasting zone is 400° ° C.-500° ° C.; and the temperature range of the sixth heating and roasting zone is 60° C.-100° C.

As a further improvement of the present invention, in the steps (2) and (4), the length of each section of heating and roasting zone is 2-6 m.

As a further improvement of the present invention, in the step (3), a colored filler is added to at least one of the synthetic liquid high-frequency material layer and the synthetic liquid film.

As a further improvement of the invention, the colored filler is a carbide.

As a further improvement of the invention, the step (4) further comprises the steps of hot pressing a copper foil on the back surface of the semi-cured high-frequency material layer, curing the semi-cured high-frequency material layer, and integrating the same with the cured film to form a novel double-sided material layer structure of a high-frequency circuit board.

As a further improvement of the present invention, the synthetic liquid high-frequency material layer is the same as the material of the synthetic liquid film.

A novel material layer structure of a high-frequency circuit board prepared by performing the method is characterized by comprising a lower copper foil layer, a cured film layer and a semi-cured high-frequency material layer, which are successively stacked from bottom to top.

As a further improvement of the present invention, the cured film layer is any one of a PI film, an MPI film, an LCP film, a TFP film and a PTFE film.

As a further improvement of the present invention, the semi-cured high-frequency material layer is an MPI film, an LCP film, a TFP film, a PTFE film, an LDK high-frequency functional adhesive, or a mixture of the LDK high-frequency functional adhesive with a copper ion migration resistant adhesive.

As a further improvement of the present invention, a release paper or PET release film is provided on the semi-cured high-frequency material layer.

As a further improvement of the present invention, a copper foil layer is hot-pressed on the semi-cured high-frequency material layer; the semi-cured high-frequency material layer is the same as the material of the cured film layer; and the semi-cured high-frequency material layer is integrated with the cured film layer.

As a further improvement of the present invention, at least one of the cured film layer and the semi-cured high-frequency material layer is a colored layer.

The invention has the following beneficial effects.

(1) A novel material layer structure of the high-frequency circuit board is produced by using the coating process. As an integral structure, this novel material layer structure of the high-frequency circuit board can be used as a circuit board manufacturing material in subsequent circuit board manufacturing processes; and a circuit board structure such as a single-layer circuit board, a multi-layer flexible circuit board and a multi-layer soft-hard combined board can be manufactured by subsequent direct hot-pressing processes with other materials or circuit boards, which brings great convenience for subsequent circuit board manufacturing. Therefore, it can simplify the manufacturing process, accelerate the manufacturing speed of the circuit board, shorten the processing time of the product, improve the processing capacity of the process and reduce the production cost. Furthermore, the product structure is optimized and the product performance is improved.

(2) MPI film, LCP film, TFP film or PTFE film, instead of the traditional PI thin film, is used as the substrate required for preparing the novel material layer structure of the high-frequency circuit board, which can not only improve the stability and dimensional stability of the overall performance of the circuit board, but also have high-frequency characteristics. It can transmit high-frequency signals, speed up the transmission speed of high-frequency signals, and achieve high-speed transmission of high-frequency signals, with low power consumption and high-frequency signal transmission loss, improving the signal transmission performance of the circuit board. It can adapt to the current high-frequency and high-speed trend from wireless networks to terminal applications, especially for new 5G technology products.

(3) Specifically, an Mpi film, an LCP film, a TFP film, a PTFE film, an LDK high-frequency functional adhesive, or a mixture of the LDK high-frequency functional adhesive and the copper ion migration resistant adhesive are used as the semi-cured high-frequency material layer to replace the traditional semi-cured AD adhesive, so that the prepared new material layer structure of the circuit board has high-frequency characteristics, can transmit high-frequency signals, and speed up the transmission speed of high-frequency signals to achieve high-speed transmission of high-frequency signals with low power consumption and high-frequency signal transmission loss, further improving the signal transmission performance of circuit board. It can adapt to the current high-frequency and high-speed trend from wireless networks to terminal applications, especially for new 5G technology products.

The above is an overview of the technical scheme of the invention. The following is a further explanation of the invention in combination with the attached drawings and specific implementations.

### BRIEF DESCRIPTION OF THE DRAWINGS

FIG. 1 is a structurally cross-section view according to Embodiment 1;

FIG. 2 is a structurally cross-section view according to Embodiment 2;

### DETAILED DESCRIPTION OF THE INVENTION

In order to further explain the technical means and effects of the present invention for achieving the intended purpose, the following detailed description of the embodiments of the present invention will be made with reference to the accompanying drawings and preferred embodiments.

### Embodiment 1

This embodiment provides a method for coating and forming a novel material layer structure of a high-frequency circuit board, comprising the steps of:
(1) placing a copper foil on a coater, and coating a synthetic liquid film on the copper foil with the copper foil as a substrate;
(2) delivering the copper foil coated with the synthetic liquid film into a tunnel oven, and successively passing the same through a plurality of sections of heating and roasting zones in the tunnel oven at a speed of 0.5-20 m/s for roasting in sections, so as to form a cured film on the copper foil, and obtaining a single-sided board; specifically, the plurality of sections of heating and roasting zones at least comprise a first heating and roasting zone, a second heating and roasting zone, a third heating and roasting zone, a fourth heating and roasting zone, a fifth heating and roasting zone and a sixth heating and roasting zone, wherein the temperature range of the first heating and roasting zone is 60° C.-100° C.; the temperature range of the second heating and roasting zone is 100° C.-200° C.; the temperature range of the third heating and roasting zone is 200° C.-300° ° C.; the temperature range of the fourth heating and roasting zone is 300° C.-400° C.; the temperature range of the fifth heating and roasting zone is 400° C.-500° C.; the temperature range of the sixth heating and roasting zone is 60° C.-100° C.; and the length of each section of heating and roasting zone is 2-6 m;
(3) placing the single-sided board on a coater, and coating the cured film of the single-sided board with a layer of a synthetic liquid high-frequency material;
(4) delivering the single-sided board coated with the synthetic liquid high-frequency material layer to the tunnel oven, and successively passing the same through a plurality of sections of heating and roasting zones in the tunnel oven at a speed of 0.5-20 m/s for roasting in sections until the synthetic liquid high-frequency material layer on the single-sided board becomes a semi-cured high-frequency material layer, so as to obtain a novel material layer structure of a high-frequency circuit board. Specifically, the plurality of sections of heating and roasting zones in the tunnel oven at least comprise a first heating and roasting zone, a second heating and roasting zone, a third heating and roasting zone, a fourth heating and roasting zone, a fifth heating and roasting zone and a sixth heating and roasting zone, wherein the temperature range of the first heating and roasting zone is 60° C.−100° C.; the temperature range of the second heating and roasting zone is 100° C.-200° ° C.; the temperature range of the third heating and roasting zone is 200° C.-300° C.; the temperature range of the fourth heating and roasting zone is 300° C.-400° C.; the temperature range of the fifth heating and roasting zone is 400° C.-500° C.; the temperature range of the sixth heating and roasting zone is 60° C.-100° C.; and the length of each section of heating and roasting zone is 2-6 m;
The step (4) further comprises the steps of: applying a release paper or PET release film on the back surface of the semi-cured high-frequency material layer, thereby obtaining a single-sided material layer structure of the high-frequency circuit board, and protecting the semi-cured high-frequency material layer with the release paper or PET release film.

The novel material layer structure of the high-frequency circuit board prepared in this embodiment can form a single-layer circuit board in a later process as long as a circuit is formed on a copper foil, and then a layer of PI film and a layer of adhesive are successively hot-pressed on the copper foil on which the circuit is formed.

Meanwhile, after forming a circuit on the copper foil, the novel material layer structure of the high-frequency circuit board prepared in this embodiment is laminated in multiple groups to form a multi-layer flexible circuit board. In the specific lamination, the semi-cured high-frequency material layer of the novel material layer structure of the first group of high-frequency circuit boards is laminated together with the copper foil formed with the circuit in the novel material layer structure of the second group of high-frequency circuit boards.

Meanwhile, a multi-layer soft-hard combining board can be formed by integrally hot-pressing the novel material layer structure of the high-frequency circuit board onto a glass fabric with an adhesive on both sides, hot-pressing a copper foil on one side of the glass fabric away from the material layer structure of the circuit board, and then forming a circuit on the copper foil, wherein the adhesive of the both sides of the glass fabric is at least one of an copper ion migration resistant adhesive and an LDK high-frequency functional adhesive.

Of course, it is also possible to directly hot-press the novel material layer structure of the high-frequency circuit board to other circuit boards, and the semi-cured high-frequency material layer on the novel material layer structure of the high-frequency circuit board and the other circuit boards are in contact and hot-pressed and integrated.

Specifically, in the step (1), the synthetic liquid film is any one of a synthetic liquid PI film, a synthetic liquid MPI film, a synthetic liquid LCP film, a synthetic liquid TFP film, and a synthetic liquid PTFE film. After high-temperature roasting in the tunnel oven, the synthetic liquid PI film, the synthetic liquid MPI film, the synthetic liquid LCP film, the synthetic liquid TFP film and the synthetic liquid PTFE film become a cured PI film, a cured MPI film, a cured LCP film, a cured TFP film and a cured PTFE film, respectively. The synthetic liquid film is obtained by stirring and melting a film in a cured or semi-cured state into a liquid state; namely, the synthetic liquid PI film is obtained by stirring and melting a PI film in a cured or semi-cured state into a liquid state; the synthetic liquid MPI film is obtained by stirring and melting the MPI film in a cured or semi-cured state into a liquid state; the synthetic liquid LCP film is obtained by stirring and melting the LCP film in a cured or semi-cured state into a liquid state; the synthetic liquid TFP film is obtained by stirring and melting the TFP film in a cured or semi-cured state into a liquid state; and the synthetic liquid PTFE film is obtained by stirring and melting the PTFE film in a cured or semi-cured state into a liquid state.

Specifically, the PI film, MPI film, LCP film, TFP film and PTFE film include the characteristics and advantages respectively.

Pi film is polyimide film, which is a good film-like insulating material, and is prepared from pyromellitic dianhydride (PMDA) and diamino diphenyl ether (DDE) by polycondensation and casting in a strong polar solvent and then imidization. Pi film has excellent high and low temperature resistance, electrical insulation, adhesion, radiation resistance and dielectric resistance, and can be used for a long time in the temperature range of −269° C.˜280° C., which can reach high temperature of 400° C. in a short time. The vitrification temperatures are 280° ° C. (Upilex R), 385° C. (Kapton) and above 500° C. (Upilex S), respectively. The tensile strength is 200 MPa at 20° C. and greater than 100 MPa at 200° C. It is particularly suitable as a substrate for flexible circuit boards.

MPI (Modified PI) is a modified polyimide, i. e. modified by a polyimide (PI) formulation. MPI, because it is a non-crystalline material, has a wide operating temperature. It is easy to handle during the copper foil pressing at low temperature, has a surface capable of bonding with copper, and is inexpensive. Specifically, the fluoride formulation is improved, so that the MPI film can transmit a high-frequency signal of 10-15 GHz. Using MPI film as the substrate required for preparing the novel material layer structure of the high-frequency circuit board in the embodiment is particularly suitable for preparing a flexible circuit board for the purpose of high-speed, stable reception and transmission of information; and terminal applications include such as 5G mobile phones, high-frequency signal transmission fields, automatic driving, radar, cloud servers and smart homes.

With speed measurement, the technical indicators of MPI film include:

| Performance | | Test Value | | Standard |
|---|---|---|---|---|
| Peel strength (kgf/cm) | (A) | 0.84 | | ≤0.7 |
| Dielectric constant Dk | 10 GHz | 2.79 | | ≤3.0 |
| Loss factor Df | 10 GHz | 0.0049 | | ≤0.005 |
| Dimensional | Method B | MD: 0.03 TD: 0.02 | | ≤±0.15 |
| stability (%) | Method C | MD: 0.06 TD: 0.04 | | |
| Resistance (%) | 10% | 0.77 | reduction | ≤20% |
| | HCl/10 min | | rate = 8.3% | |
| | 10% | 0.83 | reduction | |
| | NaOH/10 min | | rate = 1.2% | |
| | IPA/10 min | 0.76 | reduction | |
| | | | rate = 9.5% | |

| | | | |
|---|---|---|---|
| Flame retardancy | UL-94 V0 | Pass | UL-94 V0 |

It can be seen from the above that the MPI film has the following properties.
(1) Low Dk value, low Df value;
(2) Excellent heat aging resistance;
(3) Excellent dimensional stability;
(4) Excellent chemical Resistance.

Therefore, using the MPI film as the substrate required for preparing the novel material layer structure of the circuit board in the embodiment can not only improve the stability and dimensional stability of the overall performance of the circuit board, but also can transmit high-frequency signals, and accelerate the transmission speed of high-frequency signals and reduce power consumption and high-frequency signal transmission loss to improve the signal transmission performance of the circuit board, so as to adapt to the current high-frequency and high-speed trend from wireless networks to terminal applications, especially suitable for new 5G technology products.

LCP, all known as Liquid Crystal Polymer, is a novel thermoplastic organic material that generally exhibit a liquid crystalline property in the molten state. LCP film is a liquid crystal polymer film. LCP film has the properties of high strength, high rigidity, high temperature resistance, thermal stability, bendability, dimensional stability, and good electrical insulation, etc., and has better water resistance than PI film. Therefore, it is a film-type material superior to the PI film. LCP film can achieve high-frequency and high-speed soft board with high reliability. LCP films have the following excellent electrical characteristics.

(1) A constant dielectric constant can be maintained in all radio frequency ranges up to 110 GHz with good consistency; and the specific value of dielectric constant Dk is 2.9.

(2) Tangent loss is very small, only 0.002, even only increased to 0.0045 at 110 GHZ, which is very suitable for millimeter wave applications.

(3) The thermal expansion characteristic is very small. It can be used as an ideal high-frequency packaging material.

The use of LCP film as the substrate required for forming the high-frequency circuit board in this embodiment can not only improve the stability and dimensional stability of the overall performance of the circuit board, but also have less LCP film material medium loss and conductor loss due to the smoother overall LCP film; meanwhile, it has flexibility and sealing, can transmit high-frequency signals, and accelerate the transmission speed of high-frequency signals, which can improve the signal transmission performance of the circuit board and can adapt to the current high-frequency high-speed trend from wireless network to terminal applications.

Specifically, it can effectively improve the speed at which the circuit board transmits the command issued by the central area (chip) in the working state, and quickly transmit the command to each component, so that the device (such as mobile phone and communication base station device) can operate quickly without the phenomena of slowness or jam, and the communication process is smooth as a whole. Therefore, LCP film has a good prospect for high-frequency devices, especially for new 5G technology products.

Meanwhile, the LCP soft board made of LCP film as the substrate has better flexibility, which can further improve the space efficiency compared with PI soft board. Flexible electronics can be further thinned with a smaller bend radius. Therefore, the pursuit of flexibility is also a manifestation of miniaturization. According to the judgment of resistance change of more than 10%, under the same experimental conditions, LCP soft board can endure more bending times and smaller bending radius than traditional PI soft board, so that LCP soft board has better flexibility performance and product reliability. The excellent flexibility makes it possible to design the shape of LCP soft board freely so as to make full use of the narrow space in smart phones and further improve the efficiency of space utilization.

Therefore, a miniaturized high-frequency high-speed LCP soft board can be manufactured using an LCP film as a substrate.

TFP is a unique thermoplastic material with the following properties compared to conventional PI materials.

(1) Low dielectric constant: a low Dk value, the Dk value being specifically 2.55; while the Dk value of conventional PI is 3.2; therefore, the signal propagation speed is faster, the thickness is thinner, and the spacing is closer; and the power processing capacity is higher.

(2) Ultra-low material loss.

(3) Ultrahigh temperature performance, withstanding a high temperature of 300° C.

(4) The moisture absorption rate is relatively low.

Therefore, using the TFP film as the substrate required for preparing the novel material layer structure of the high-frequency circuit board in the embodiment can not only improve the stability and dimensional stability of the overall performance of the circuit board, but also can transmit high-frequency signals, and accelerate the transmission speed of high-frequency signals and reduce power consumption and high-frequency signal transmission loss to improve the signal transmission performance of the circuit board, so as to adapt to the current high-frequency and high-speed trend from wireless networks to terminal applications, suitable for new 5G technology products.

PTFE, polytetrafluoroethylene, is also named Teflon. Polytetrafluoro ethylene (PTFE) has excellent dielectric properties, chemical resistance, heat resistance and flame resistance, and has small dielectric constant and dielectric loss and small change in high-frequency range. The main performances are as follows.
1. Electrical performance
   (1) Dielectric constant: 2.1;
   (2) Dielectric loss: 5×10⁻⁴;
   (3) Volume resistance: 1018Ω·cm;
2. Chemical performance: acid-alkali resistance, organic solvent resistance and oxidation resistance;
3. Thermal stability: long-term operation in the temperature range of −200° C.-260° ° C.;
4. Flame retardancy: UL94V-0;
5. Weather resistance: there is no significant loss of mechanical properties outdoors for more than 20 years.

Therefore, using the PTFE film as the substrate required for preparing the novel material layer structure of the circuit board in the embodiment can not only improve the stability and dimensional stability of the overall performance of the circuit board, but also can transmit high-frequency signals, and accelerate the transmission speed of high-frequency signals and reduce power consumption and high-frequency signal transmission loss to improve the signal transmission performance of the circuit board, so as to adapt to the current high-frequency and high-speed trend from wireless networks to terminal applications, suitable for new 5G technology products.

The integration of 5G base station makes the demand of high-frequency copper clad laminate grow rapidly. As one of the mainstream high-frequency base materials of 5G high-frequency high-speed copper clad laminate, PTFE will meet the huge market growth in the 5G era.

It can be seen therefrom that using any one of the above-mentioned PI film, MPI film, LCP film, TFP film and PTFE film as the substrate required for preparing the novel material layer structure of the high-frequency circuit board in the embodiment is particularly suitable for a flexible circuit board. Especially, the MPI film, LCP film, TFP film and PTFE film can not only improve the overall performance of the flexible circuit board, but also have a high-frequency characteristic, which can greatly accelerate the transmission of high-frequency signals, achieve high-speed transmission of high-frequency signals, and reduce power consumption and high-frequency signal transmission loss, particularly suitable for novel 5G technology products.

Specifically, in the step (3), the synthetic liquid high-frequency material layer is a synthetic liquid MPI film, a synthetic liquid LCP film, a synthetic liquid TFP film, a synthetic liquid PTFE film, a synthetic liquid LDK high-frequency functional adhesive, or a synthetic liquid mixture of a liquid LDK high-frequency functional adhesive and a liquid copper ion migration resistant adhesive. After the high-temperature roasting in the tunnel oven, the synthetic liquid MPI film, the synthetic liquid LCP film, the synthetic liquid TFP film, the synthetic liquid PTFE film, the synthetic liquid LDK high-frequency functional adhesive, or the synthetic liquid mixture of the liquid LDK high-frequency functional adhesive and the liquid copper ion resistant adhesive becomes a semi-cured MPI film, a semi-cured LCP film, a semi-cured TFP film, a semi-cured PTFE film, a semi-cured LDK high-frequency functional adhesive, and a mixture of the semi-cured LDK high-frequency functional adhesive and the copper ion migration resistant adhesive, respectively.

It can be seen from the above that the semi-cured MPI film, semi-cured LCP film, semi-cured TFP film and semi-cured PTFE film are all high-frequency thin film materials which can accelerate the frequency and speed of signal transmission, transmit high-frequency signals and improve the signal transmission performance of the circuit board, which can not only improve the overall performance of the flexible circuit board, but also have high-frequency characteristics and can greatly accelerate the transmission of high-frequency signals and achieve high-speed transmission of high-frequency signals. They are particularly suitable for new 5G technology products.

However, the synthetic liquid LDK high-frequency functional adhesive is obtained by adding the Teflon or LCP material to the liquid AD adhesive. However, the molecular distribution in the semi-cured LDK high-frequency functional adhesive is more compact and uniform, which does not consume energy, so that the LDK high-frequency functional adhesive has the functions of improving the signal transmission frequency and resisting magnetic interference, so as to improve the signal transmission performance of the circuit board. Specifically, it can effectively improve the speed at which the circuit board transmits the command issued by the central area (chip) in the working state, and quickly transmit the command to each component, so that the device (such as mobile phone and communication base station device) can operate rapidly without the phenomena of slowness and jam, and the whole communication process of new 5G technology products is smooth.

In the case of the liquid copper ion migration resistant adhesive, it is obtained by adding a reagent such as a copper ion scavenger to the liquid AD adhesive, followed by high purification. In particular, the liquid AD adhesive may be a conventional AD adhesive. Optionally, the copper ion scavenger can be an inorganic ion exchangers (for example, IXE-700F, IXE-750, etc.) which have the ability to capture copper ions, and can prevent the migration of copper ions between circuits. After adding the copper ion scavenger to the AD adhesive, the copper ion scavenger has no effect on the performance of the AD adhesive, but can improve the performance stability of the AD adhesive. The conventional AD adhesive contains epoxy resin, tackifier, plasticizer and various fillers; and after a high purification process, the purity of the epoxy resin component in the AD adhesive is improved, and the possibility of migration of copper ions between circuits from the AD adhesive is significantly reduced, achieving the purpose of resisting migration of copper ions. Specifically, the conventional AD adhesive has a certain gap between each two components, and copper ions can migrate through the gap; however, when the concentration of the epoxy resin purified from the conventional AD adhesive is increased, the concentration of other components is significantly reduced, and the gap existing between the epoxy resin and other components is greatly reduced, thereby reducing the gap available for copper ion migration, so as to achieve the purpose of resisting copper ion migration. Since the copper ion migration resistant adhesive has the anti-copper ion migration function of the low-particle material, it can effectively ensure that the circuit can work safely and effectively in the working state, and there will be no ion migration phenomenon between the circuits, so as to prevent the conducting collision between the circuits during the use of the device, resulting in short circuit and combustion and explosion hazards, so that the circuit plays a good safeguard and protection role.

When the synthetic liquid high-frequency material layer is a mixture of a liquid LDK high-frequency functional adhesive and a liquid copper ion migration resistant adhesive, it is sufficient to mix the liquid LDK high-frequency functional adhesive and the liquid copper ion migration resistant adhesive, so that the semi-cured high-frequency material layer has both high-speed transmission high-frequency signals and copper ion migration resistant properties.

In this embodiment, the synthetic liquid film and the synthetic liquid high-frequency material layer may be made of the same material or may be made of different materials. For example, the synthetic liquid film and the synthetic liquid high-frequency material layer are both of a film type; or the synthetic liquid film is of a film type, and the synthetic liquid high-frequency material layer is of a adhesive type. When the synthetic liquid film and the synthetic liquid high-frequency material layer are both films, the optimal method is that the synthetic liquid film and the synthetic liquid high-frequency material layer are both MPI films; the synthetic liquid film and the synthetic liquid high-frequency material layer are both LCP films; the synthetic liquid film and the synthetic liquid high-frequency material layer are both TFP films; or the synthetic liquid film and the synthetic liquid high-frequency material layer are both PTFE films.

In the step (3), the synthetic liquid high-frequency material layer and the synthetic liquid film may be the color of the material itself or may be a transparent color.

Of course, a colored filler can also be added to at least one of the synthetic liquid high-frequency material layer and the synthetic liquid film. In particular, the colored filler can be a carbide or other colored filler. The synthetic liquid high-frequency material layer (which can be specifically a synthetic liquid MPI film, a synthetic liquid LCP film, a synthetic liquid TFP film, a synthetic liquid PTFE film, a synthetic liquid LDK high-frequency functional adhesive, or a synthetic liquid mixture of the liquid LDK high-frequency functional adhesive and a liquid copper ion resistant adhesive) and the synthetic liquid film (which can be specifically any one of a synthetic liquid PI film, a synthetic liquid MPI film, a synthetic liquid LCP film, a synthetic liquid TFP film and a synthetic liquid PTFE film) can exhibit black color after being added with a colored filler. Whether the novel material layer structure of the high-frequency circuit board prepared in this embodiment is made into a single-layer circuit board, a multi-layer flexible circuit board, or a multi-layer soft-hard combined board, the black semi-cured high-frequency material layer and the cured film layer have a shielding effect on the circuit, which can prevent the internal circuit from being exposed, and prevent the external person from seeing the internal circuit from the outside, and play the role of concealing and protecting the circuit on the circuit board; meanwhile, it plays the role of masking defects for the circuit board or circuit with impurities or defects.

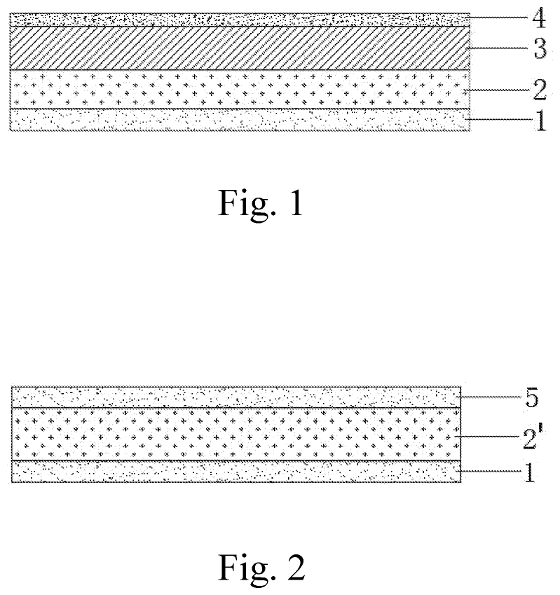

The present embodiment also provides a novel material layer structure of a high-frequency circuit board prepared by performing the above-mentioned method, as shown in FIG. 1, comprising a lower copper foil layer 1, a cured film layer 2 and a semi-cured high-frequency material layer 3 which are successively stacked from bottom to top.

Specifically, the cured film layer 2 is any one of a PI film, an MPI film, an LCP film, a TFP film, and a PTFE film. Using any one of the above-mentioned PI film, MPI film, LCP film, TFP film and PTFE film as the substrate required for preparing the novel material layer structure of the high-frequency circuit board in the embodiment is particularly suitable for a flexible circuit board. Especially, the MPI film, LCP film, TFP film and PTFE film can not only improve the overall performance of the flexible circuit board, but also have a high-frequency characteristic, which can greatly accelerate the transmission of high-frequency signals and achieve high-speed transmission of high-frequency signals, particularly suitable for novel 5G technology products.

Specifically, the semi-cured high-frequency material layer 3 is an MPI film, an LCP film, a TFP film, a PTFE film, an LDK high-frequency functional adhesive, or a mixture of the LDK high-frequency functional adhesive with a copper ion migration resistant adhesive. MPI film, LCP film, TFP film, PTFE film and LDK high-frequency functional adhesive can accelerate the frequency and speed of signal transmission, transmit high-frequency signals and improve the signal transmission performance of the circuit board, which can not only improve the overall performance of the flexible circuit board, but also have high-frequency characteristics. They can greatly accelerate the transmission of high-frequency signals and achieve high-speed transmission of high-frequency signals, especially suitable for new 5G technology products. However, the mixture of LDK high-frequency functional adhesive and copper ion migration resistant adhesive has high-speed transmission high-frequency signals and copper ion migration resistant performance.

In this embodiment, the cured film layer 2 and the semi-cured high-frequency material layer 3 may be made of the same material or may be made of different materials. For example, the cured film layer 2 and the semi-cured high-frequency material layer 3 are both a film type, or the cured film layer 2 is a film type; and the semi-cured high-frequency material layer 3 is an adhesive type. When the cured film layer 2 and the semi-cured high-frequency material layer 3 are both films, it is preferable that the cured film layer 2 and the semi-cured high-frequency material layer 3 are both MPI films; the cured film layer 2 and the semi-cured high-frequency material layer 3 are both LCP films; the cured film layer 2 and the semi-cured high-frequency material layer 3 are both TFP films; or the cured film layer 2 and the semi-cured high-frequency material layer 3 are both PTFE films.

Specifically, at least one of the cured film layer 2 and the semi-cured high-frequency material layer 3 is a colored layer. The colored layer can be specifically black; and the colored layer plays the role of shielding, protection, masking and so on for the internal circuit.

In the embodiment, a release layer 4 is provided on the semi-cured high-frequency material layer 3; the release layer 4 is a release paper or a PET release film, protecting the semi-cured high-frequency material layer 3; and the release layer 4 can be peeled off during subsequent processing.

### Embodiment 2

The main differences between this embodiment and Embodiment 1 are as follows: the step (4) further comprises the steps of hot pressing a copper foil on the back surface of the semi-cured high-frequency material layer, curing the semi-cured high-frequency material layer, and integrating the same with the cured film to form a novel double-sided material layer structure of a high-frequency circuit board, instead of applying a release paper or PET release film on the back of the semi-cured high-frequency material layer.

Meanwhile, the synthetic liquid high-frequency material layer described in this embodiment is the same as the material of the synthetic liquid film. Therefore, in the case where the synthetic liquid film is any one of a PI film, an MPI film, an LCP film, a TFP film, and a PTFE film, the synthetic liquid high-frequency material layer is also a corresponding material. For example, the synthetic liquid film and the synthetic liquid high-frequency material layer are both MPI films; the synthetic liquid film and the synthetic liquid high-frequency material layer are both LCP films; the synthetic liquid film and the synthetic liquid high-frequency material layer are both TFP films; or the synthetic liquid film and the synthetic liquid high-frequency material layer are both PTFE films.

Therefore, a double-sided novel material layer structure of a high-frequency circuit board can be prepared by the above-mentioned method; and a copper foil layer 5 is hot-pressed on the semi-cured high-frequency material layer 3, as shown in FIG. 2, to form a novel double-sided material layer structure of a circuit board. Meanwhile, the material of the semi-cured high-frequency material layer 3 is the same as that of the cured film layer 2, both being of a film type. Since the copper foil layer 5 is hot-pressed, the semi-cured high-frequency material layer 3 is cured and integrated with the cured film layer 2, namely, integrated into a synthetic film layer 2′.

In the description above, only the preferred embodiments of the present invention has been described, and the technical scope of the present invention is not limited in any way. Therefore, other structures obtained by adopting the same or similar technical features as those of the above embodiments of the present invention are within the scope of the present invention.

1. A method for coating and forming a novel material layer structure of a high-frequency circuit board, characterized by comprising the steps of:
(1) placing a copper foil on a coater, and coating a synthetic liquid film on the copper foil with the copper foil as a substrate;
(2) delivering the copper foil coated with the synthetic liquid film into a tunnel oven, and successively passing the same through a plurality of sections of heating and roasting zones in the tunnel oven at a speed of 0.5-20 m/s for roasting in sections, so as to form a cured film on the copper foil, and obtaining a single-sided board;
(3) placing the single-sided board on a coater, and coating the cured film of the single-sided board with a layer of a synthetic liquid high-frequency material; and
(4) delivering the single-sided board coated with the synthetic liquid high-frequency material layer to the tunnel oven, and successively passing the same through a plurality of sections of heating and roasting zones in the tunnel oven at a speed of 0.5-20 m/s for roasting in sections until the synthetic liquid high-frequency material layer on the single-sided board becomes a semi-cured high-frequency material layer, so as to obtain a novel material layer structure of a high-frequency circuit board.

2. The method for coating and forming a novel material layer structure of a high-frequency circuit board according to claim 1, characterized in that the step (4) further comprises the steps of applying a release paper or PET release film on the back of the semi-cured high-frequency material layer.

3. The method for coating and forming a novel material layer structure of a high-frequency circuit board according to claim 1, characterized in that in the step (1), the synthetic liquid film is any one of a synthetic liquid PI film, a synthetic liquid MPI film, a synthetic liquid LCP film, a synthetic liquid TFP film, and a synthetic liquid PTFE film.

4. The method for coating and forming a novel material layer structure of a high-frequency circuit board according to claim 1, wherein in the step (3), the synthetic liquid high-frequency material layer is a synthetic liquid MPI film, a synthetic liquid LCP film, a synthetic liquid TFP film, a synthetic liquid PTFE film, a synthetic liquid LDK high-frequency functional adhesive, or a synthetic liquid mixture of a liquid LDK high-frequency functional adhesive and a liquid copper ion migration resistant adhesive.

5. The method for coating and forming a novel material layer structure of a high-frequency circuit board according to claim 4, characterized in that the synthetic liquid LDK high-frequency functional adhesive is obtained by adding Teflon or LCP material to a liquid AD adhesive; and the liquid copper ion migration resistant adhesive is obtained by adding a copper ion scavenger to the liquid AD adhesive, followed by high purification.

6. The method for coating and forming a novel material layer structure of a high-frequency circuit board according to claim 1, characterized in that in the step (2), the plurality of sections of heating and roasting zones in the tunnel oven at least comprise a first heating and roasting zone, a second heating and roasting zone, a third heating and roasting zone, a fourth heating and roasting zone, a fifth heating and roasting zone and a sixth heating and roasting zone, wherein the temperature range of the first heating and roasting zone is 60° C.-100° C.; the temperature range of the second heating and roasting zone is 100° C.-200° C.; the temperature range of the third heating and roasting zone is 200° C.-300° C.; the temperature range of the fourth heating and roasting zone is 300° C.-400° C.; the temperature range of the fifth heating and roasting zone is 400° C.-500° C.; and the temperature range of the sixth heating and roasting zone is 60° C.-100° C.

7. The method for coating and forming a novel material layer structure of a high-frequency circuit board according to claim 1, characterized in that in the step (4), the plurality of sections of heating and roasting zones in the tunnel oven at least comprise a first heating and roasting zone, a second heating and roasting zone, a third heating and roasting zone, a fourth heating and roasting zone, a fifth heating and roasting zone and a sixth heating and roasting zone, wherein the temperature range of the first heating and roasting zone is 60° C.-100° C.; the temperature range of the second heating and roasting zone is 100° C.-200° C.; the temperature range of the third heating and roasting zone is 200° C.-300° C.; the temperature range of the fourth heating and roasting zone is 300° C.-400° C.; the temperature range of the fifth heating and roasting zone is 400° C.-500° C.; and the temperature range of the sixth heating and roasting zone is 60° C.-100° C.

8. The method for coating and forming a novel material layer structure of a high-frequency circuit board according to claim 1, characterized in that in the steps (2) and (4), the length of each section of heating and roasting zone is 2-6 m.

9. The method for coating and forming a novel material layer structure of a high-frequency circuit board according to claim 1, characterized in that in the step (3), a colored filler is added to at least one of the synthetic liquid high-frequency material layer and the synthetic liquid film.

10. The method for coating and forming a novel material layer structure of a high-frequency circuit board according to claim 9, characterized in that the colored filler is carbide.

11. The method for coating and forming a novel material layer structure of a high-frequency circuit board according to claim 3, characterized in that the step (4) further comprises the steps of hot pressing a copper foil on the back surface of the semi-cured high-frequency material layer, curing the semi-cured high-frequency material layer, and integrating the same with the cured film to form a novel double-sided material layer structure of a high-frequency circuit board.

12. The method for coating and forming a novel material layer structure of a high-frequency circuit board according to claim 11, characterized in that the synthetic liquid high-frequency material layer is the same as the material of the synthetic liquid film.

13. A novel material layer structure of a high-frequency circuit board prepared by performing the method according to claim 1, characterized by comprising a lower copper foil layer, a cured film layer and a semi-cured high-frequency material layer, which are successively stacked from bottom to top.

14. The novel material layer structure of a high-frequency circuit board according to claim 13, characterized in that the cured film layer is any one of a PI film, an MPI film, an LCP film, a TFP film and a PTFE film.

15. The novel material layer structure of a high-frequency circuit board according to claim 13, characterized in that the semi-cured high-frequency material layer is an MPI film, an LCP film, a TFP film, a PTFE film, an LDK high-frequency functional adhesive, or a mixture of the LDK high-frequency functional adhesive with a copper ion migration resistant adhesive.

16. The novel material layer structure of a high-frequency circuit board according to claim 13, characterized in that a release paper or PET release film is provided on the semi-cured high-frequency material layer.

17. The novel material layer structure of a high-frequency circuit board according to claim 14, characterized in that a copper foil layer is hot-pressed on the semi-cured high-frequency material layer; the semi-cured high-frequency material layer is the same as the material of the cured film layer; and the semi-cured high-frequency material layer is integrated with the cured film layer.

18. The novel material layer structure of a high-frequency circuit board according to claim 13, characterized in that at least one of the cured film layer and the semi-cured high-frequency material layer is a colored layer.
